(19) United States
(12) Patent Application Publication
(10) Pub. No.: US 2026/0096219 A1
(43) Pub. Date: Apr. 2, 2026

(54) ELECTROSTATIC DISCHARGE PROTECTION DEVICE AND CIRCUIT

(71) Applicant: Vanguard International Semiconductor Corporation, Hsinchu (TW)

(72) Inventors: Ting-Yu CHANG, Zhubei City (TW); Jian-Hsing LEE, Hsinchu City (TW); Yeh-Ning JOU, Hsinchu City (TW); Chih-Hsuan LIN, Hsinchu City (TW); Chieh-Yao CHUANG, Kaohsiung City (TW); Hsien-Feng LIAO, Taichung City (TW)

(73) Assignee: Vanguard International Semiconductor Corporation, Hsinchu (TW)

(21) Appl. No.: 18/903,925

(22) Filed: Oct. 1, 2024

(51) Int. Cl. H01L 27/02; H01L 29/74

(52) U.S. Cl. CPC H10D 89/60; H10D 18/00

(57) ABSTRACT

An electrostatic discharge protection device and an electrostatic discharge protection circuit are provided. The electrostatic discharge protection device includes first to fifth well regions, first to fifth P-type doped regions, and first and second N-type doped regions. The first to fifth P-type doped regions and the first and second N-type doped regions are disposed in the first to fifth well regions and the fourth and fifth well regions disposed on a deep N-type well region in a P-type semiconductor substrate. The conductivity types of the first, third and fourth well regions are P-type. The conductivity types of the second and fifth well regions are N-type. The second and fifth P-type doped regions and the second N-type doped region are electrically connected to the first power pad. The first, third and fourth P-type doped regions and the first N-type doped region are electrically connected to the second power pad.

### BACKGROUND OF THE INVENTION

### Field of the Invention

The present disclosure relates to an electrostatic discharge protection device, and, in particular, it relates to the structure and the circuitry of an electrostatic discharge protection device.

### Description of the Related Art

Damage to electronic devices caused by electrostatic discharge (ESD) has become one of the most important reliability issues for integrated circuit products today. As the size of the integrated circuit products continues to shrink to deep sub-micron levels, the gate oxide layer of metal-oxide-semiconductor field-effect transistors is becoming thinner and thinner. Therefore, these integrated circuits are more susceptible to damage due to ESD.

In general industry standards, the input and output pins (I/O pins) of an integrated circuit product must be able to pass ESD testing of both the human-body model (HBM) and the machine model (MM). The required voltage level for the HBM ESD testing is more than 2000 volts, and the required voltage level for MM ESD testing is more than 200 volts. Therefore, ESD components in integrated circuit products need to be arranged close to all of the I/O pads to protect the internal core circuit from ESD currents.

### BRIEF SUMMARY OF THE INVENTION

An embodiment of the disclosure provides an electrostatic discharge protection device. The electrostatic discharge protection device includes a P-type semiconductor substrate, a deep N-type well region, a first well region, a first P-type doped region, a second well region, a second P-type doped region, a third well region, a third P-type doped region, a fourth well region, a fourth P-type doped region, a first N-type doped region, a fifth well region, a fifth P-type doped region, and a second N-type doped region. The deep N-type well region is disposed in the P-type semiconductor substrate. The first well region is disposed on the deep N-type well region. The first P-type doped region is disposed in the first well region. The second well region is disposed on the deep N-type well region. The second P-type doped region is disposed in the second well region. The third well region is disposed on the deep N-type well region. The third P-type doped region is disposed in the third well region. The fourth well region is disposed on the deep N-type well region. The fourth P-type doped region is disposed in the fourth well region. The first N-type doped region is disposed in the fourth well region. The fifth well region is disposed on the deep N-type well region. The fifth P-type doped region is disposed in the fifth well region. The second N-type doped region is disposed in the fifth well region. The conductivity types of the first, third and fourth well regions are P-type. The conductivity types of the second and fifth well regions are N-type. The second P-type doped region, the fifth P-type doped region and the second N-type doped region are electrically connected to the first power pad. The first P-type doped region, the third P-type doped region, the fourth P-type doped region and the first N-type doped region are electrically connected to the second power pad.

An embodiment of the disclosure provides an electrostatic discharge protection circuit for protecting a core circuit. The electrostatic discharge protection circuit includes a first PNP bipolar junction transistor, a second PNP bipolar junction transistor, a first diode, a third PNP bipolar junction transistor, a first NPN bipolar junction transistor, the fourth PNP bipolar junction transistor, a second NPN bipolar junction transistor, a first resistor, a second resistor, a third resistor and a fourth resistor. The emitter of the first PNP bipolar junction transistor is coupled to the first power pad. The collector of the first PNP bipolar junction transistor is coupled to the second power pad. The emitter of the second PNP bipolar junction transistor is coupled to the second power pad. The collector of the second PNP bipolar junction transistor is coupled to the third power pad. The cathode of the first diode is coupled to the first power pad and the base of the second PNP bipolar junction transistor. The anode of the first diode is coupled to the third power pad. The emitter of the third PNP bipolar junction transistor is coupled to the first power pad. The base of the third PNP bipolar junction transistor is coupled to the base of the first PNP bipolar junction transistor. The emitter of the first NPN bipolar junction transistor is coupled to the second power pad. The base of the first NPN bipolar junction transistor is coupled to the collector of the third PNP bipolar junction transistor. The collector of the first NPN bipolar junction transistor is coupled to the base of the third PNP bipolar junction transistor to form a first semiconductor controlled rectifier. The emitter of the fourth PNP bipolar junction transistor is coupled to the first power pad. The emitter of the second NPN bipolar junction transistor is coupled to the second power pad. The base of the fourth PNP bipolar junction transistor is coupled to the collector of the second NPN bipolar junction transistor. The collector of the fourth PNP bipolar junction transistor is coupled to the base of the second NPN bipolar junction transistor to form a second semiconductor controlled rectifier. The base of the first NPN bipolar junction transistor is coupled to the base of the second NPN bipolar junction transistor. The first resistor is coupled between the first power pad and the base of the first PNP bipolar junction transistor. The second resistor is coupled between the first power pad and the base of the fourth PNP bipolar junction transistor. The third resistor is coupled between the second power pad and the base of the first NPN bipolar junction transistor. The fourth resistor is coupled between the second power pad and the base of the second NPN bipolar junction transistor.

### BRIEF DESCRIPTION OF THE DRAWINGS

The present invention can be more fully understood by reading the subsequent detailed description and examples with references made to the accompanying drawings, wherein:

FIG. 1 is a schematic diagram of an operating system in accordance with some embodiments of the disclosure;

FIG. 2 is a schematic top view of an electrostatic discharge protection device in accordance with some embodiments of the disclosure;

FIG. 3 is a schematic cross-sectional view along the line A-A′ and the line B-B′ of the electrostatic discharge protection device of FIG. 2 in accordance with some embodiments of the disclosure;

FIG. 4 is a schematic top view of an electrostatic discharge protection device in accordance with some embodiments of the disclosure;

FIG. 5 is a schematic cross-sectional view along the line A-A′ and the line B-B′ of the electrostatic discharge protection device of FIG. 4 in accordance with some embodiments of the disclosure;

FIG. 6 is a schematic connection diagram of an equivalent circuit of the electrostatic discharge protection device of FIGS. 2 and 3 in the operating system in accordance with some embodiments of the disclosure, showing an equivalent discharge circuit when an electrostatic discharge event occurs between a first voltage source and a second voltage source;

FIG. 7 illustrates the parasitic elements of the equivalent discharge circuit of FIG. 6 at the corresponding positions of the electrostatic discharge protection device of FIG. 3;

FIG. 8 is a schematic connection diagram of an equivalent circuit of the electrostatic discharge protection device of FIGS. 4 and 5 in the operating system in accordance with some embodiments of the disclosure, showing an equivalent discharge circuit when an electrostatic discharge event occurs between a first voltage source and a second voltage source; and

FIG. 9 illustrates the parasitic elements of the equivalent discharge circuit of FIG. 8 at the corresponding positions of the electrostatic discharge protection device of FIG. 5.

### DETAILED DESCRIPTION OF THE INVENTION

The following description is made for the purpose of illustrating the general principles of the invention and should not be taken in a limiting sense. The scope of the invention is best determined by reference to the appended claims.

Silicon controlled rectifiers (SCR) is used as electrostatic discharge protection circuits because of the advantages of, such as low trigger voltage (Vt1), low holding voltage (V_{Hold}), low on-resistance (Ron), etc. It has better human-body model (HBM) performance and mechanical model (MM) performance. However, silicon-controlled rectifiers with low holding voltage are susceptible to false triggering by noise voltage spikes. Therefore, an electrostatic discharge protection device and an electrostatic discharge protection circuit are needed to solve the above problems.

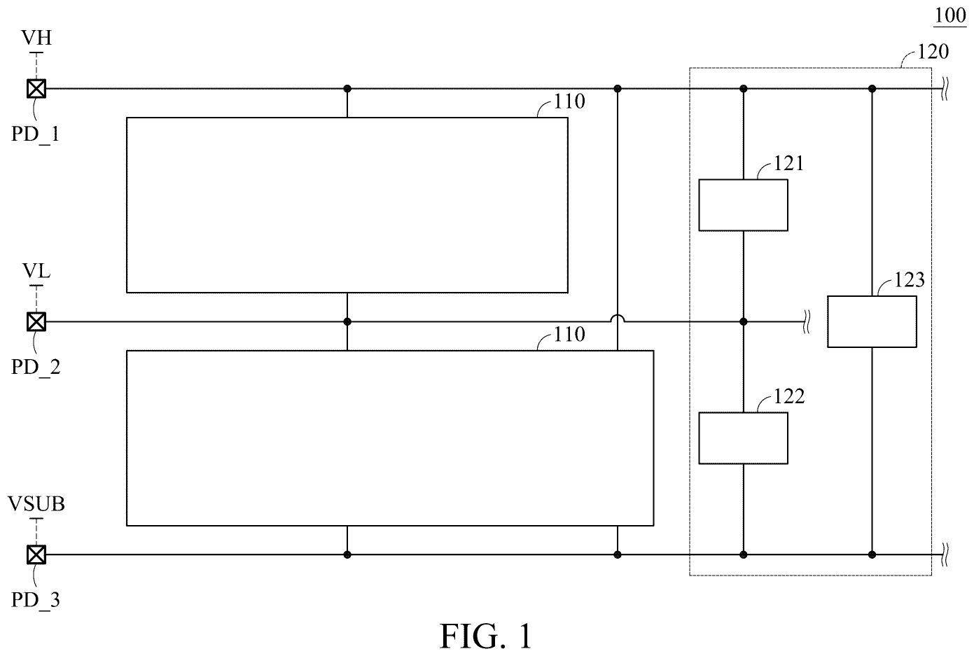

FIG. 1 is a schematic diagram of an operating system in accordance with some embodiments of the disclosure. As shown in FIG. 1, an operating system 100 includes an electrostatic discharge protection circuit 110 (including electrostatic discharge protection circuits 110A and 110B in following figures) and a core circuit 120. The electrostatic discharge protection circuit 110 and the core circuit 120 are coupled to power pads PD_1, PD_2 and PD_3. In this embodiment, the electrostatic discharge protection circuit 110 is configured to protect the core circuit 120, thereby preventing electrostatic discharge current from one of the power pads PD_1, PD_2, and PD_3 from entering and damaging the core circuit 120.

In some embodiments, the core circuit 120 includes a circuit 121, a circuit 122, and a circuit 123. The circuit 121 is coupled between the power pad PD_1 and the power pad PD_2. The circuit 122 is coupled between the power pad PD_2 and the power pad PD_3. The circuit 123 is coupled between the power pad PD_1 and the power pad PD_3. The present disclosure does not limit the number of circuits of the core circuit 120. In some embodiments, the core circuit 120 has more or fewer circuits. Each of the circuits is coupled between at least two power pads.

When an electrostatic discharge event does not occur, the operating system 100 operates in the normal mode. In the normal mode, the electrostatic discharge protection circuit 110 does not work. At this time, the power pad PD_1 may receive an operating voltage VH, the power pad PD_2 may receive an operating voltage VL, and the power pad PD_3 may receive an operating voltage VSUB. The circuit 121 works according to the operating voltage VH and the operating voltage VL. The circuit 122 works according to the operating voltage VL and the operating voltage VSUB. The circuit 123 works according to the operating voltage VH and the operating voltage VSUB. In some embodiments, the operating voltage VH is greater than the operating voltage VL, and the operating voltage VL is greater than the operating voltage VSUB.

When an electrostatic discharge event occurs, the operating system 100 operates in a protection mode. In the protection mode, the electrostatic discharge protection circuit 110 releases the electrostatic discharge current from one of the power pad PD_1, the power pad PD_2, and the power pad PD_3 to prevent the electrostatic discharge current from entering the core circuit 120. For example, when an electrostatic discharge event occurs at the power pad PD_1, and the power pad PD_2 and the power pad PD_3 are coupled to ground, the electrostatic discharge protection circuit 110 provides a conducting path so that the electrostatic discharge current flows from the power pad PD_1, passes through the electrostatic discharge protection circuit 110, and enters the power pad PD_2 and the power pad PD_3.

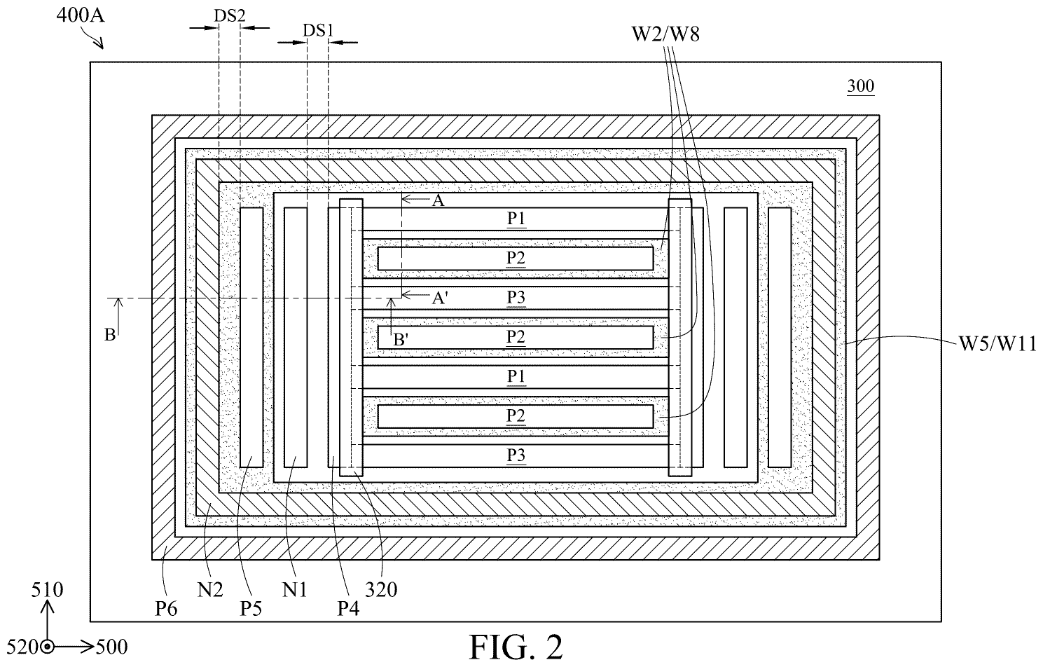

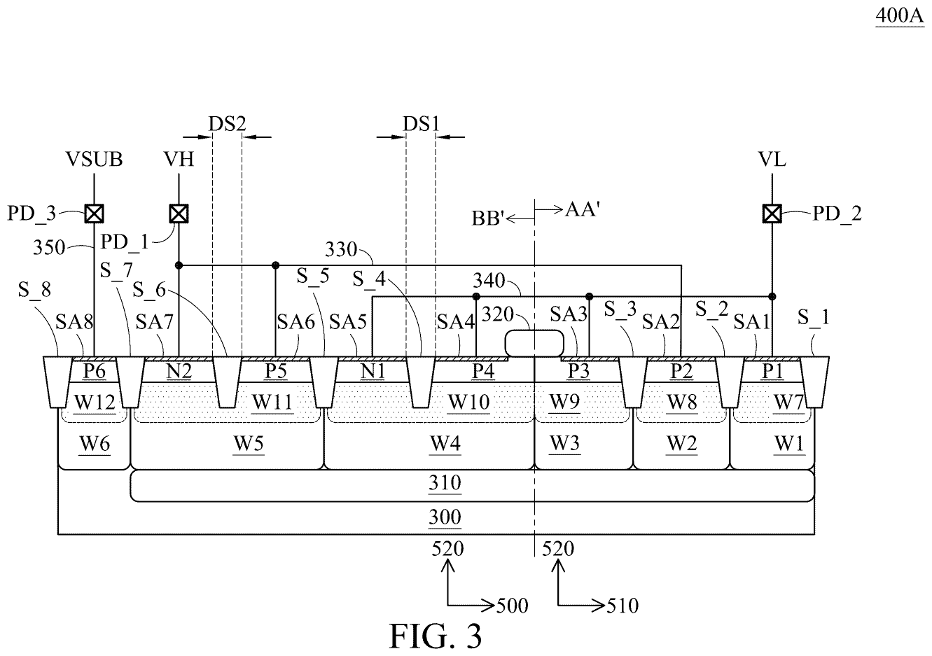

FIG. 2 is a schematic top view of an electrostatic discharge protection device 400A of the electrostatic discharge protection circuit 110 in accordance with some embodiments of the disclosure. FIG. 3 is a schematic cross-sectional view along the line A-A′ and the line B-B′ of the electrostatic discharge protection device 400A of FIG. 2 in accordance with some embodiments of the disclosure. FIG. 2 also illustrates the layouts of well regions W2, W5, W8, and W11 and the doped regions P1, P2, P3, P4, P5, P6, N1, and N2 of the electrostatic discharge protection device 400A. For simplification, other elements in FIG. 3 are omitted and not shown in FIG. 2.

As shown in FIGS. 2 and 3, the electrostatic discharge protection device 400A includes a P-type semiconductor substrate 300, a deep N-type well region (DNW) 310, a well region W1, a well region W2, a well region W3, a well region W4, a well region W5, a doped region P1, a doped region P2, a doped region P3, a doped region P4, a doped region P5, a doped region N1 and a doped region N2.

In some embodiments, the P-type semiconductor substrate 300 may be a P-type semiconductor substrate. The above-mentioned semiconductor substrate includes an elementary semiconductor including silicon (Si) or germanium (Ge), etc.; a compound semiconductor including gallium nitride (GaN), silicon carbide (SiC), gallium arsenide (GaAs), gallium phosphide (GaP), indium phosphide (InP), indium arsenide (InAs), indium antimonide (InSb), etc. ; an alloy semiconductor including SiGe, GaAsP, AlInAs, AlGaAs, GaInAs, GaInP, GaInAsP, or a combination thereof. In addition, the P-type semiconductor substrate 300 may also be a P-type semiconductor on insulator (SOI).

The deep N-type well region 310 is disposed in the P-type semiconductor substrate 300. The well regions W1 to W5 are all arranged on the deep N-type well region 310. The well regions W1 and W2 are arranged side by side and adjacent to each other along the direction that is substantially parallel to the line A-A′ (the direction 510). The well regions W2 and W3 are arranged side by side along the direction 510 and adjacent to each other. Moreover, the well regions W1 and W3 are respectively located on opposite sides of the well region W2 along the direction 510.

The well regions W3 and W4 are arranged side by side and adjacent to each other along the direction that is substantially parallel the line B-B′ (the direction 500). The well regions W4 and W5 are arranged side by side along the direction 500 and adjacent to each other. Moreover, the well regions W3 and W5 are respectively located on opposite sides of the well region W4 along the direction 500.

In this embodiment, the conductivity types of the well region W1, the well region W3 and the well region W4 are P-type. The conductivity types of the well region W2 and the well region W5 are the N-type. Furthermore, the bottom surfaces of the well regions W1 to W5 are connected to the deep N-type well region 310. The well region W2 and the well region W5 may be electrically connected to each other through the deep N-type well region 310.

In some embodiments, the impurity concentrations of the well regions W1, W3, and W4 are similar and are greater than the impurity concentration of the P-type substrate 300. The impurity concentrations of the well regions W2 and W5 are similar and are greater than the impurity concentration of the deep N-type well region 310.

The doped region P1 is provided in the well region W1. The doped region P2 is disposed in the well region W2. The doped region P3 is disposed in the well region W3. The doped region P4 is disposed in the well region W4. The doped region P5 is disposed in the well region W5. Furthermore, the doped regions P1 to P5 may extend from the top surface of the P-type semiconductor substrate 300 into a portion of the P-type semiconductor substrate 300. As shown in FIG. 2, opposite sides of the doped region P4 are respectively adjacent to the doped region P1 and the doped region P3. The doped region P4 is adjacent to the doped region P3 and is separated from the doped region P2.

In this embodiment, in the direction substantially parallel to the line B-B′ (the direction 500), the doped region P4 is located between the doped region P3 (or the doped region P1) and the doped region N1. In addition, the doped region N1 is located between the doped region P4 and the doped region P5.

As shown in FIG. 2, in some embodiments, the doped regions P1 to P3 are arranged substantially extending along the direction 500 and parallel to each other. The doped regions P4, P5, and N1 are arrange substantially extending along the direction 510 and parallel to each other. The doped region N2 is a ring-shaped structure surrounding the doped regions P1 to P5 and the doped region N1.

In some embodiments, the conductivity types of the doped regions P1 to P5 are P-type. The impurity concentrations of the doped regions P1 to P5 are similar and are greater than the impurity concentrations of the well regions W1, W3, and W4.

The doped region N1 is disposed in the well region W4. The doped region N2 is disposed in the well region W5. In some embodiments, the conductivity types of the doped regions N1 and N2 are N-type. The impurity concentrations of the doped regions N1 and N2 are greater than the impurity concentrations of the well regions W2 and W5.

In some embodiments, the electrostatic discharge protection device 400A further includes a well region W6 and a doped region P6. The well region W6 is disposed in the P-type semiconductor substrate 300. The doped region P6 is disposed in the well region W6. As shown in FIG. 2, in some embodiments, the doped region P6 is a ring-shaped structure surrounding the doped region N2.

In some embodiments, the conductivity types of the well region W6 and the doped region P6 are P-type. The impurity concentration of the doped region P6 is greater than the impurity concentration of the well region W6. The impurity concentration of the well region W6 is similar to the impurity concentration of the well region W1. The impurity concentration of the doped region P6 is similar to the impurity concentration of the doped region P1.

The types of well regions W1 to W6 are not limited in the present disclosure. When the impurity concentrations of the well regions W1 to W6 are low (e.g., lower than a threshold value), the well regions W1 to W6 may serve as high-voltage well regions. At this time, the maximum value of the operating voltage VH of the electrostatic discharge protection device 400A can reach a first value. When the impurity concentrations of the well regions W1 to W6 are high (for example, higher than the threshold value), the well regions W1 to W6 may serve as low-voltage well regions. At this time, the maximum value of the operating voltage VH of the electrostatic discharge protection device 400A can reach a second value. In this case, the first value is greater than the second value. In other embodiments, the type of one of the well regions W1 to W6 is different from the type of another of the well regions W1 to W6. For example, at least one of the well regions W1 to W6 is a low-voltage well, and the others are high-voltage wells. In this case, the maximum value of the operation voltage VH may be between the first and second values.

In a possible embodiment, the well regions W1, W3, W4 and W6 are called high-voltage N-type well regions (HVPW). In addition, the well regions W2 and W5 are called high-voltage N-type well regions (HVNW).

In some embodiments, the electrostatic discharge protection device 400A further includes a well region W7, a well region W8, a well region W9, a well region W10, a well region W11 and a well region W12. The well region W7 is disposed on the well region W1. In addition, the well region W7 is disposed between the well region W1 and the doped region P1 in a direction substantially perpendicular to the top surface of the P-type semiconductor substrate 300 (the direction 520). Furthermore, the conductivity type of the well region W7 is P-type. The impurity concentration of the well region W7 is greater than the impurity concentration of the well region W1 and less than the impurity concentration of the doped region P1. The well region W8 is disposed in the well region W2. In addition, the well region W8 is disposed between the well region W2 and the doped region P2 in the direction 520. Furthermore, the conductivity type of the well region W8 is N-type. The impurity concentration of the well region W8 is greater than the impurity concentration of the well region W2 and less than the impurity concentrations of the doped regions N1 and N2. The well region W9 is disposed in the well region W3. In addition, the well region W9 is disposed between the well region W3 and the doped region P3 in the direction 520. Furthermore, the conductivity type of the well region W9 is a P-type. The impurity concentration of the well region W9 is greater than the impurity concentration of the well region W3 and less than the impurity concentration of the doped region P3. The well region W10 is disposed in the well region W4. In addition, the well region W10 is disposed between the well region W4 and the doped region P4 (or between the well region W4 and the doped region N1) in the direction 520. Furthermore, the conductivity type of the well region W10 is P-type. The impurity concentration of the well region W10 is greater than the impurity concentration of the well region W4 and less than the impurity concentration of the doped region P4. The well region W11 is disposed in the well region W5. In addition, the well region W11 is disposed between the well region W5 and the doped region P5 (or between the well region W5 and the doped region N2) in the direction 520. Furthermore, the conductivity type of the well region W11 is N-type. The impurity concentration of the well region W11 is greater than the impurity concentration of the well region W5 and less than the impurity concentration of the doped region N1. The well region W12 is disposed in the well region W6. In addition, the well region W12 is disposed between the well region W6 and the doped region P6 in the direction 520. In addition, the conductivity type of the well region W12 is P-type. The impurity concentration of the well region W12 is greater than the impurity concentration of the well region W6 and less than the impurity concentration of the doped region P6.

The impurity concentrations of well regions W7, W9, W10, and W12 are similar. In addition, the impurity concentrations of well regions W8 and W11 are similar. In a possible embodiment, the well regions W7, W9, W10 and W12 are called low-voltage N-type well regions (LVPW), and well regions W8 and W11 are called low-voltage N-type well regions (LVNW). In this embodiment, well regions W1, W3, W4, and W6 are called high-voltage P-type well regions (HVPW), and well regions W2 and W5 are called high-voltage N-type well regions (HVNW).

In some embodiments, when the well regions W7 to W12 are respectively disposed in the well regions W1 to W6, the maximum value of the operating voltage VH of the electrostatic discharge protection device 400A may reach a third value. In this embodiment, the third value is greater than the first value. For example, the third value may be 20V.

In some embodiments, multiple ion implantation processes may be performed to implant P-type and N-type dopants in the P-type semiconductor substrate 300 to form the deep N-type well region 310, the well regions W1 to W12, the doped regions P1 to P6 and the doped regions N1 and N2. In some embodiments, the N-type dopant may include phosphorus, arsenic, nitrogen, antimony, or a combination thereof. In some embodiments, the N-type dopant may include boron, gallium, aluminum, indium, boron trifluoride ions (BF3+), or a combination thereof. In some embodiments, the well regions W1, W3, W4 and W6 may be simultaneously formed by the same ion implantation process, or respectively formed by different ion implantation processes. The well regions W2 and W5 may be simultaneously formed by the same ion implantation process, or respectively formed by different ion implantation processes. The well regions W7, W9, W10 and W12 may be simultaneously formed by the same ion implantation process, or respectively formed by different ion implantation processes. The well regions W8 and W11 may be simultaneously formed by the same ion implantation process, or respectively formed by different ion implantation processes. The doped regions P1 to P6 may be simultaneously formed by the same ion implantation process, or respectively formed by different ion implantation processes. The doped regions N1 and N2 respectively may be simultaneously formed by the same ion implantation process, or respectively formed by different ion implantation processes.

In some embodiments, the electrostatic discharge protection structure 400A further includes a resistive protective oxide (RPO) 320. As shown in FIG. 2, in some embodiments, the resistive protection oxide 320 overlaps portions of doped regions P1, P3, and P4. As shown in FIG. 3, the resistance protection oxide 320 is disposed on the P-type semiconductor substrate 300, covers a portion of the doped region P3 close to the doped region P4, and extends to cover the doped region P4. In some embodiments, the resistive protection oxide 320 is used to block silicide forbidden regions, to prevent subsequence silicide to be formed thereon by the silicide process, so as to maintain the electrical performances of the silicide forbidden regions and to increase the resistance value of the surface of the P-type semiconductor substrate 200. In some embodiments, the resistive protection oxide 320 is used to cut-off the silicide feature formed on the top surface of the P-type semiconductor substrate 300 at the interface between the doped region P3 and the doped region P4. In some embodiments, the resistive protective oxide 320 may be formed using a chemical vapor deposition (CVD) process or another suitable process. In some embodiments, the material of the resistive protective oxide 320 may include silicon dioxide, silicon nitride, silicon oxynitride, or another suitable dielectric material.

The electrostatic discharge protection structure 400A also includes silicide features SA1, SA2, SA3, SA4, SA5, SA6, SA7, SA8 formed on the top surface of the P-type semiconductor substrate 300. More specifically, the silicide feature SA1 completely covers the doped region P1. The silicide feature SA2 completely covers the doped region P2. The silicide feature SA3 covers the portion of the doped region P3 that is not covered by the resistive protection oxide 320. The silicide feature SA4 covers the portion of the doped region P4 that is not covered by the resistance protection oxide 320 (that is, the top surface of the P-type semiconductor substrate 300 at the interface between the doped region P3 and the doped region P4 is not covered by the silicide feature). The silicide feature SA5 completely covers doped region N1. The silicide feature SA6 completely covers doped region P5. The silicide feature SA7 completely covers the doped region N2. The silicide feature SA8 completely covers doped region P6. Furthermore, the silicide features SA1 to SA8 are spaced apart from each other.

In some embodiments, the silicide features SA1 to SA8 include metal silicides (such as tungsten silicide, titanium silicide, cobalt silicide, nickel silicide, platinum silicide, erbium silicide, another suitable metal silicide, or a combination thereof). In some embodiments, a metal layer is entirely deposited by chemical vapor deposition (CVD) (such as low pressure vapor deposition (LPCVD) or plasma enhanced chemical vapor deposition (PECVD)), physical vapor deposition (PVD) (such as resistive heating evaporation, electron beam evaporation, or sputtering), electroplating, atomic layer deposition (ALD), another suitable process, or a combination thereof. Then, an annealing process is performed, so that the metal layer on a portion of the doped regions P1 to P8, N1 and N2 not covered by the resistive protective oxide 320 may react with the underlying semiconductor material to form the silicide features SA1 to SA8. Afterwards, the unreacted metal layer is removed.

The electrostatic discharge protection structure 400A further includes isolation features S_1, S_2, S_3, S_4, S_5, S_6, S_7, and S_8. The isolation features S_1 to S_8 are formed on the top surface of the P-type semiconductor substrate 300 and extend into a portion of the P-type semiconductor substrate 300. More specifically, the doped region P1 is located between the isolation feature S_1 and the isolation feature S_2. The isolation feature S_2 isolates the doped region P1 from the doped region P2. The isolation feature S_2 further isolates the well region W7 from the well region W8. The isolation feature S_3 isolates the doped region P2 from the doped region P3. The isolation feature S_3 further isolates the well region W8 from the well region W9. The isolation feature S_4 is located in the well region W10 and isolates the doped region P4 from the doped region N1. In this embodiment, the isolation feature S_5 isolates the doped region N1 from the doped region P5. The isolation feature S_5 further isolates the well region W10 from the well region W11. The isolation feature S_6 is located in the well region W11 and isolates the doped region P5 from the doped region N2. The isolation feature S_7 isolates the doped region N2 from the doped region P6. The isolation feature S_7 further isolates the well region W11 from the well region W12. In addition, the doped region P6 is located between the isolation feature S_7 and the isolation feature S_8. In some embodiments, there is no isolation feature located between well region W9 and the well region W10.

In some embodiments, the isolation features S_1 to S_8 include field oxide (FOX) layers formed by a local oxidation of silicon (LOCOS) process, shallow trench isolation (STI) structures formed by a deposition process, or another suitable isolation structure. In some embodiments, the isolation features S_1 to S_8 are formed by a thermal oxidation process, including a dry oxidation process, a wet oxidation process, or another suitable thermal oxidation process.

The electrostatic discharge protection device 400A further includes interconnect structures 330, 340, and 350. The interconnect structure 330 is electrically connected to the power pad PD_1. Furthermore, the interconnect structure 330 is directly connected to the silicide features SA2, SA6, and SA7. Moreover, the interconnect structure 330 is electrically connected to the doped regions P2, P5, and N1 through the silicide features SA2, SA6, and SA7. The interconnect structure 340 is electrically connected to the power pad PD_2. In addition, the interconnect structure 340 is directly connected to the silicide features SA1, SA3, SA4, and SA5. Furthermore, the interconnect structure 340 is electrically connected to the doped regions P1, P3, P4 and N1 through the silicide features SA1, SA3, SA4, and SA5. The interconnect structure 350 is electrically connected to the power pad PD_3. In addition, the interconnect structure 350 is directly connected to the silicide feature SA8. Furthermore, the interconnect structure 350 is electrically connected to the doped region P6 through the silicide feature SA8. In this embodiment, the power pad PD_1 receives the operating voltage VH. The power pad PD_2 receives the operating voltage VL. In addition, the power pad PD_3 receives the operating voltage VSUB.

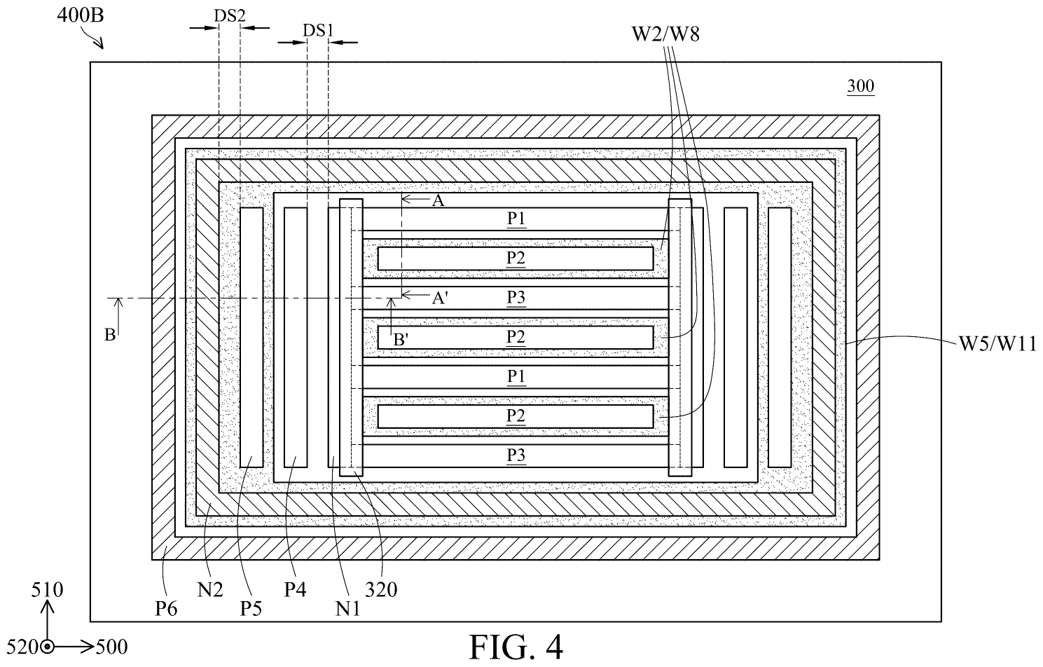

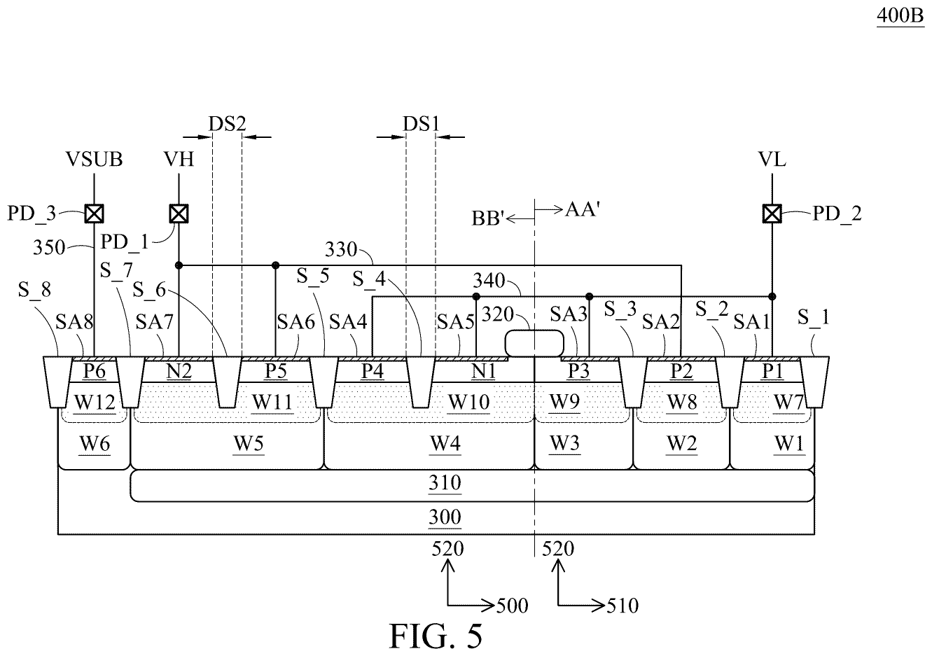

FIG. 4 is a schematic top view of an electrostatic discharge protection device 400B of the electrostatic discharge protection circuit 110 in accordance with some embodiments of the disclosure. FIG. 5 is a schematic cross-sectional view along the line A-A′ and the line B-B′ of the electrostatic discharge protection device400B of FIG. 4 in accordance with some embodiments of the disclosure. FIG. 4 also illustrates the layouts of the well regions W2, W5, W8, and W11, the doped regions P1 to P6 and the doped regions N1 and N2 of the electrostatic discharge protection device 400B. For simplification, other elements in FIG. 5 are omitted and not shown in FIG. 4. FIG. 4 is similar to FIG. 2, except for the opposite sides of the doped region N1 of the electrostatic discharge protection device 400B respectively adjacent to the doped region P1 and the doped region P3. The doped region N1 is adjacent to the doped region P3. Moreover, the doped region N1 is separated from the doped region P2. Moreover, in the direction 500, the doped region N1 is located between the doped region P3 and the doped region P4, and the doped region P4 is located between the doped region N1 and the doped region P5. The resistive protection oxide 320 overlaps portions of the doped regions P3 and N1 to cut off the silicide features SA3 and SA5 formed on the surface at the interface between the doped regions P3 and N1.

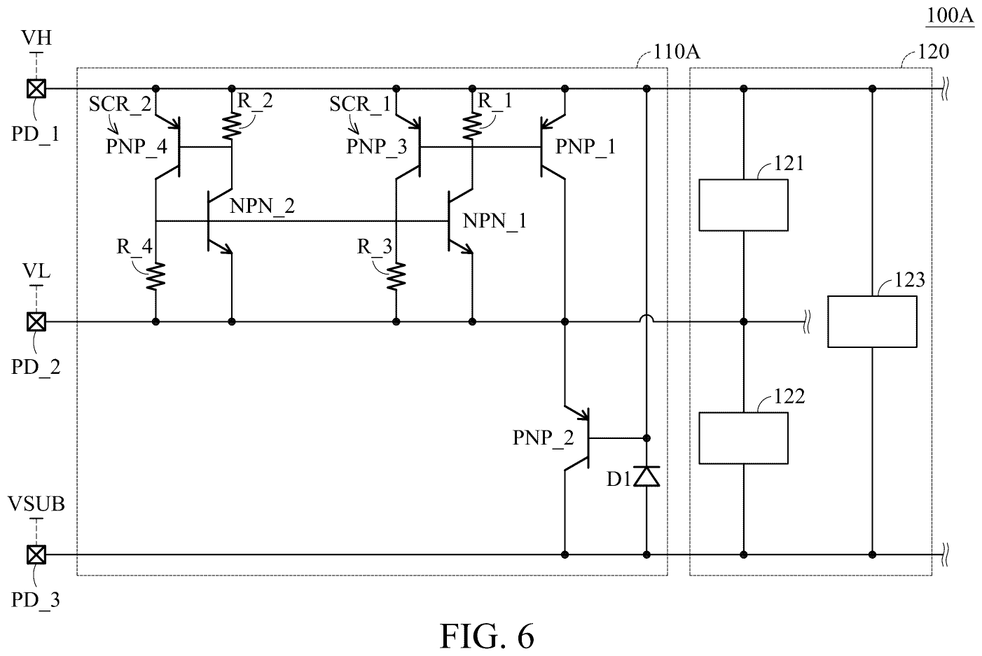

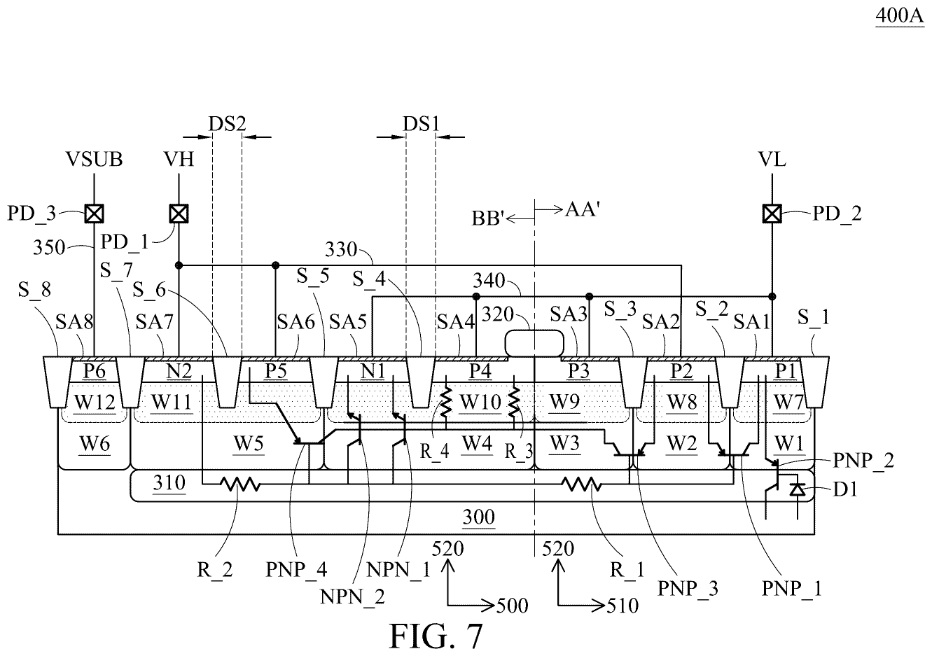

FIG. 6 is a schematic connection diagram of an equivalent circuit of the electrostatic discharge protection device 400A of FIGS. 2 and 3 in the operating system in accordance with some embodiments of the disclosure, showing an equivalent discharge circuit when an electrostatic discharge event occurs between the power pads PD_1 and PD_2. FIG. 7 illustrates the parasitic elements of the equivalent discharge circuit of FIG. 6 at the corresponding positions of the electrostatic discharge protection device 400A of FIG. 3.

As shown in FIGS. 6 and 7, when an electrostatic discharge event occurs between the power pads PD_1 and PD_2, the equivalent discharge circuit of the electrostatic discharge protection device 400A includes a parasitic PNP bipolar junction transistor PNP_1, a parasitic PNP bipolar junction transistor PNP_2, a parasitic PNP bipolar junction transistor PNP_ 3, a parasitic PNP bipolar junction transistor PNP_ 4, a parasitic NPN-type bipolar junction transistor NPN_1, a parasitic NPN bipolar junction transistor NPN_2, a parasitic resistance R_1, a parasitic resistance R_2, a parasitic resistance R_3, a parasitic resistance R_4 and a parasitic diode D1.

The doped region P2, the well region W8, the well region W2, the deep N-type well region 310, the doped region P1, the well region W7 and the well region W1 of the electrostatic discharge protection device 400A may collectively form the parasitic PNP bipolar junction transistor PNP_1. The doped region P1, well regions W7 and W1 may serve as the collector of the parasitic PNP bipolar junction transistor PNP_1. The doped region P2 may serve as the emitter of the parasitic PNP bipolar junction transistor PNP_1. The deep N-type well region 310 and the well regions W2 and W8 may serve as the base of the parasitic PNP bipolar junction transistor PNP_1. The equivalent resistance of the deep N-well region 310 may serve as the parasitic resistance R_1.

The doped region P1, the well region W7, the well region W1, the deep N-type well region 310, the well region W5, the well region W11, the doped region N2, the P-type semiconductor substrate 300, the well region W6, the well region W12 and the doped region P6 may collectively form the parasitic PNP bipolar junction transistor PNP_2. The doped region P1, the well regions W7 and W1 may serve as the emitter of the parasitic PNP bipolar junction transistor PNP_2. The deep N-type well region 310, the well regions W5 and W11 and the doped region N3 may serve as the base of the parasitic PNP bipolar junction transistor PNP_2. The P-type substrate 300, the well regions W6 and W12 and the doped region P6 may serve as the collector of the parasitic PNP bipolar junction transistor PNP_2.

The doped region P2, the well region W2, the well region W8, the deep N-type well region 310 and the well region W3 may collectively form a parasitic PNP bipolar junction transistor PNP_3. The doped region P2 may serve as the emitter of the parasitic PNP bipolar junction transistor PNP_3. The well regions W8 and W2 and the deep N-type well region 310 may serve as the base of the parasitic PNP bipolar junction transistor PNP_3. The well region W3 may serve as the collector of the parasitic PNP bipolar junction transistor PNP_3.

The doped region P5, the well region W5, the well region W11, the deep N-type well region 310 and the well region W4 may collectively form the parasitic PNP bipolar junction transistor PNP_4. The doped region P5 may serve as the emitter of the parasitic PNP bipolar junction transistor PNP_4. The well regions W11 and W15 and the deep N-type well region 310 may serve as the base of the parasitic PNP bipolar junction transistor PNP_4. The well region W4 may serve as the collector of the parasitic PNP bipolar junction transistor PNP_4. The equivalent resistances of the deep N-type well region 310 and the well regions W5 and W11 may serve as the parasitic resistance R_2.

The doped region N1, the well region W10, the well region W4, the well region W3, the deep N-type well region 310, the well region W5, the well region W11 and the doped region N2 may collectively form the parasitic NPN bipolar junction transistor NPN_1. The doped region N1 may serve as the emitter of the parasitic NPN bipolar junction transistor NPN_1. The well regions W10, W4, and W3 may serve as the base of the parasitic NPN bipolar junction transistor NPN_1. The deep N-type well region 310, the well regions W5, W11 and the doped region N2 may serve as the collector of the parasitic NPN bipolar junction transistor NPN_1.

The doped region N1, the well region W10, the well region W4, the deep N-type well region 310, the well region W5, the well region W11 and the doped region N2 may collectively form the parasitic NPN bipolar junction transistor NPN_2. The doped region N1 may serve as the emitter of the NPN bipolar junction transistor NPN_2. The well regions parasitic W10 and W4 may serve as the base of the parasitic NPN bipolar junction transistor NPN_2. The deep N-type well region 310, the well regions W5, W11 and the doped region N2 may serve as the collector of the parasitic NPN-type bipolar junction transistor NPN_2. The equivalent resistance of well region W10 may serve as the parasitic resistors R_3 and R_4.

The P-type semiconductor substrate 300, the well region W6, the well region W12, the doped region P6, the deep N-type well region 310, the well region W5, the well region W11 and the doped region N2 may collectively form the parasitic diode D1. The deep N-type well region 310, the well region W5, the well region W11 and the doped region N2 may serve as the cathode of the parasitic diode D1. The P-type semiconductor substrate 300, the well region W6, the well region W12 and the doped region P6 may serve as the anode of the parasitic diode D1.

The emitter of the parasitic PNP bipolar junction transistor PNP_1 is coupled to the power pad PD_1. The collector of the parasitic PNP bipolar junction transistor PNP_1 is coupled to the power pad PD_2. The base of the parasitic PNP bipolar junction transistor PNP_ 1 is coupled to the power pad PD_1 through the parasitic resistance R_1 formed by the deep N-type well region 310.

The emitter of the parasitic PNP bipolar junction transistor PNP_2 is coupled to the power pad PD_2. The collector of the parasitic PNP bipolar junction transistor PNP_2 is coupled to the power pad PD_3. The base of the parasitic PNP bipolar junction transistor PNP_2 is coupled to the cathode of the parasitic diode D1. The anode of the parasitic diode D1 is coupled to the power pad PD_3.

The emitter of the parasitic PNP bipolar junction transistor PNP_3 is coupled to the power pad PD_1. The base of the parasitic PNP bipolar junction transistor PNP_3 is coupled to the base of the parasitic PNP bipolar junction transistor PNP_1. Furthermore, the base of the parasitic PNP bipolar junction transistor PNP_3 is also coupled to the power pad PD_1 through the parasitic resistance R_1 formed by the deep N-type well region 310.

The emitter of the parasitic NPN bipolar junction transistor NPN_1 is coupled to the power pad PD_2. The base of the parasitic NPN bipolar junction transistor NPN_1 is coupled to the collector of the parasitic PNP bipolar junction transistor PNP_3. The collector of the parasitic NPN bipolar junction transistor NPN_1 is coupled to the base of the parasitic PNP bipolar junction transistor PNP_3 to form a parasitic semiconductor controlled rectifier SCR_1. Moreover, the collector of the parasitic NPN bipolar junction transistor NPN_1 is also coupled to the power pad PD_1 through the parasitic resistance R_1 formed by the deep N-type well region 310. In this embodiment, the collector of the parasitic PNP bipolar junction transistor PNP_3 and the base of the parasitic NPN bipolar junction transistor NPN_1 are coupled to the power pad PD_2 through the parasitic resistance R_3 formed by the well region W10.

The emitter of the parasitic PNP bipolar junction transistor PNP_4 is coupled to the power pad PD_1. The base of the parasitic PNP bipolar junction transistor PNP_4 is coupled to the collector of the parasitic NPN bipolar junction transistor NPN_2. The collector of the parasitic PNP bipolar junction transistor PNP_4 is coupled to the base of the parasitic NPN bipolar junction transistor NPN_2 to form a parasitic semiconductor controlled rectifier SCR_2. Furthermore, the base of the parasitic PNP bipolar junction transistor PNP_4 is also coupled to the power pad PD_1 through the parasitic resistor R_2 formed by the deep N-type well region 310.

The base of the parasitic NPN bipolar junction transistor NPN_2 is coupled to the base of the parasitic NPN bipolar junction transistor NPN_1. The emitter of the parasitic NPN bipolar junction transistor NPN_2 is coupled to the power pad PD_2. Furthermore, the collector of the parasitic NPN bipolar junction transistor NPN_2 is also coupled to the power pad PD_1 through the parasitic resistance R_2 formed by the deep N-type well region 310. In this embodiment, the collector of the parasitic PNP bipolar junction transistor PNP_4 and the base of the parasitic NPN bipolar junction transistor NPN_2 are coupled to the power pad PD_2 through the parasitic resistance R_4 formed by the well region W10.

FIG. 6 may also serve as a schematic diagram of the electrostatic discharge protection circuit 110A in the operating system 100 according to some embodiments of the present disclosure. The electrostatic discharge protection circuit 110A includes a PNP bipolar junction transistor PNP_1, a PNP bipolar junction transistor PNP_2, a PNP bipolar junction transistor PNP_3, a PNP bipolar junction transistor PNP_4, a NPN bipolar junction transistor NPN_1, a NPN bipolar junction transistor NPN_2, a resistor R_1, a resistor R_2, a resistor R_3, a resistor R_4 and a diode D1. In some embodiments, the PNP bipolar junction transistors PNP_1˜PNP_4, the NPN-type bipolar junction transistors NPN_1, NPN_2, the resistors R_1˜R_4 and the diode D1 share the same substrate, such as the P-type semiconductor substrate 300.

The emitter of the PNP bipolar junction transistor PNP_1 is coupled to the power pad PD_1. The collector of the PNP bipolar junction transistor PNP_1 is coupled to the power pad PD_2. The resistor R_1 is coupled between the power pad PD_1 and the base of the PNP bipolar junction transistor PNP_1.

The emitter of the PNP bipolar junction transistor PNP_2 is coupled to the power pad PD_2. The collector of the PNP bipolar junction transistor PNP_2 is coupled to the power pad PD_3.

The cathode of the diode D1 is coupled to the power pad PD_1 and the base of the PNP bipolar junction transistor PNP_ 2. The anode of diode D1 is coupled to power pad PD_3.

The emitter of the PNP bipolar junction transistor PNP_3 is coupled to the power pad PD_1. The base of the PNP bipolar junction transistor PNP_3 is coupled to the base of the PNP bipolar junction transistor PNP_1.

The emitter of the first NPN bipolar junction transistor NPN_1 is coupled to the power pad PD_2. The resistor R_3 is coupled between the power pad PD_2 and the base of the NPN bipolar junction transistor NPN_1. The base of the NPN bipolar junction transistor NPN_1 is coupled to the collector of the PNP bipolar junction transistor PNP_3. The collector of the first NPN bipolar junction transistor NPN_1 is coupled to the base of the PNP bipolar junction transistor PNP_3 to form a semiconductor controlled rectifier SCR_1.

The emitter of the PNP bipolar junction transistor PNP_4 is coupled to the power pad PD_1. The resistor R_2 is coupled between the power pad PD_1 and the base of the PNP bipolar junction transistor PNP_4. The emitter of the NPN bipolar junction transistor NPN_2 is coupled to the power pad PD_2. The resistor R_4 is coupled between the power pad PD_2 and the base of the NPN bipolar junction transistor NPN_2. The base of the PNP bipolar junction transistor PNP_4 is coupled to the collector of the NPN bipolar junction transistor NPN_2. The collector of the PNP bipolar junction transistor PNP_4 is coupled to the base of the NPN bipolar junction transistor NPN_2 to form a semiconductor controlled rectifier SCR_2. Furthermore, the base of the NPN bipolar junction transistor NPN_1 is coupled to the base of the NPN bipolar junction transistor NPN_2.

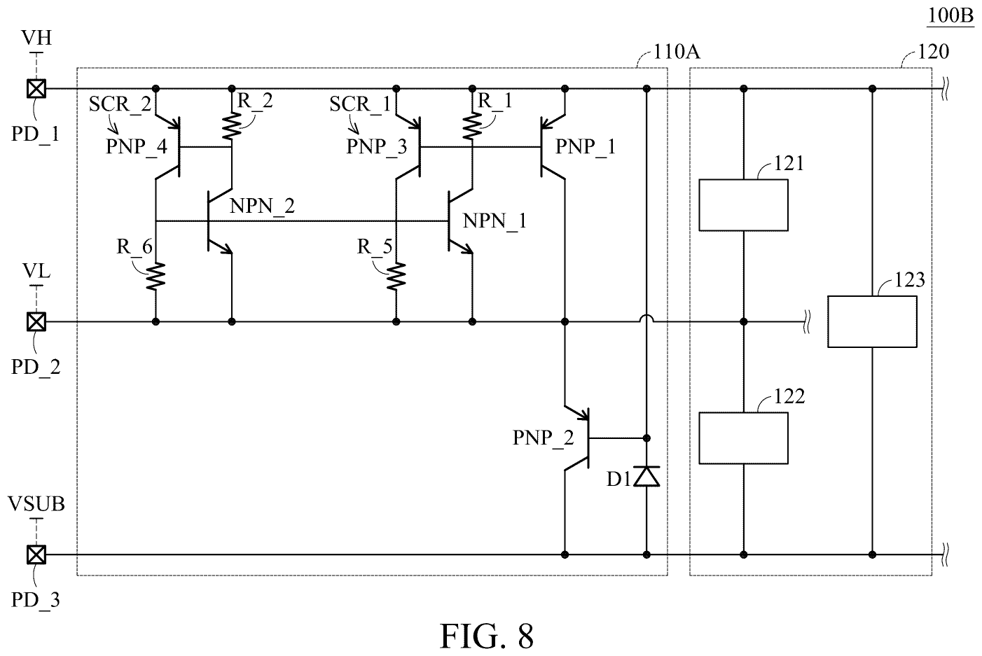

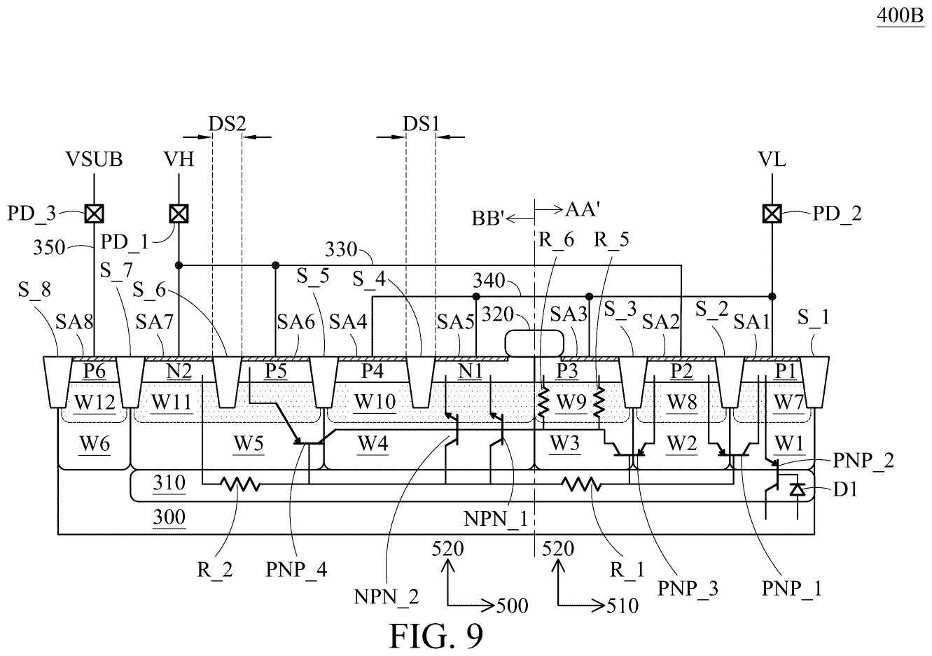

FIG. 8 is a schematic connection diagram of an equivalent circuit of the electrostatic discharge protection device 400B of FIGS. 4 and 5 in the operating system 100 in accordance with some embodiments of the disclosure, showing an equivalent discharge circuit when an electrostatic discharge event occurs between the power pad PD_1 and PD_2. FIG. 9 illustrates the parasitic elements of the equivalent discharge circuit of FIG. 8 at the corresponding positions of the electrostatic discharge protection device 400B of FIG. 5. FIG. 8 is similar to FIG. 6 with the exception that the equivalent discharge circuit of the electrostatic discharge protection device 400B includes a parasitic PNP bipolar junction transistor PNP_1, a parasitic PNP bipolar junction transistor PNP_2, a parasitic PNP bipolar junction transistor PNP_3, and a parasitic PNP bipolar junction transistor PNP_4, a parasitic NPN-type bipolar junction transistor NPN_1, a parasitic NPN-type bipolar junction transistor NPN_2, a parasitic resistance R_1, a parasitic resistance R_2, a parasitic resistance R_5, a parasitic resistance R_6 and a parasitic diode D1.

In this embodiment, the collector of the parasitic PNP bipolar junction transistor PNP_3 and the base of the parasitic NPN bipolar junction transistor NPN_1 are coupled to the power pad PD_2 through the parasitic resistance R_5 formed by the well region W9. Furthermore, the collector of the parasitic PNP bipolar junction transistor PNP_4 and the base of the parasitic NPN bipolar junction transistor NPN_2 are coupled to the power pad PD_2 through the parasitic resistance R_6 formed by the well region W9.

FIG. 8 can also be regarded as a schematic diagram of the electrostatic discharge protection circuit 110B in the operating system 100 according to some embodiments of the present disclosure. The electrostatic discharge protection circuit 110B includes a PNP bipolar junction transistor PNP_1, a PNP bipolar junction transistor PNP_2, a PNP bipolar junction transistor PNP_3, a PNP bipolar junction transistor PNP_ 4, a NPN bipolar junction transistor NPN_1, a NPN bipolar junction transistor NPN_ 2, a resistor R_1, a resistor R_2, a resistor R_5, resistor R_6 and a diode D1. In some embodiments, the PNP bipolar junction transistors PNP_1 to PNP_4, the NPN-type bipolar junction transistors NPN_1 and NPN_2, the resistor R_1, the resistor R_2, the resistor R_5, the resistor R_6 and the diode D1 share the same substrate, such as P-type semiconductor substrate 00.

The electrostatic discharge protection circuit 110B is similar to the electrostatic discharge protection circuit 110A. The differences between the electrostatic discharge protection circuits 110A and 110B include that the resistor R_5 of the electrostatic discharge protection circuit 110B is coupled between the power pad PD_2 and the base of the NPN bipolar junction transistor NPN_1. The resistor R_6 of the electrostatic discharge protection circuit 110B is coupled between the power pad PD_2 and the base of the NPN bipolar junction transistor NPN_2.

In the electrostatic discharge protection devices 400A and 400B, since the base of the parasitic PNP bipolar junction transistor PNP_3 is coupled to the base of the parasitic PNP bipolar junction transistor PNP_1, and the base of the parasitic NPN bipolar junction transistor NPN_2 is coupled to the base of the parasitic NPN bipolar junction transistor NPN_1, the equivalent circuits of the electrostatic discharge protection devices 400A and 400B show characteristics of both a PNP bipolar junction transistor and a semiconductor controlled rectifier. When an electrostatic discharge event occurs at the power pad PD_1 and the power pads PD_2 and PD_3 are coupled to ground, the emitter-base junctions of the parasitic PNP bipolar junction transistors PNP_1, PNP_3, and PNP_4 and the base-emitter junctions of the parasitic NPN bipolar junction transistors NPN_1 and NPN_2 of the electrostatic discharge protection devices 400A and 400B are forward biased, so that the parasitic PNP bipolar junction transistors PNP_1, PNP_3, PNP_4 and the parasitic NPN-type bipolar junction transistors NPN_1, NPN_2 are triggered to ON at the same time. Since the parasitic PNP bipolar junction transistors PNP_3 and PNP_4 and the parasitic NPN bipolar junction transistors NPN_1 and NPN_2 of the electrostatic discharge protection devices 400A and 400B are triggered to ON simultaneously, the parasitic semiconductor controlled rectifiers SCR-1 and SCR-2 are accordingly triggered to ON. The electrostatic discharge current may flow from the power pad PD_1, through the parasitic PNP bipolar junction transistor PNP_1 and the parasitic semiconductor controlled rectifiers SCR-1 and SCR-2 of the electrostatic discharge protection devices 400A and 400B, and entering the power pad PD_2. The electrostatic discharge protection devices 400A and 400B may prevent electrostatic discharge current from flowing through the core circuit 120 under protection.

As shown in FIGS. 6 and 8, when an electrostatic discharge event occurs at the power pad PD_1 and the power pads PD_2 and PD_3 are coupled to ground, the emitter-base junctions of the PNP bipolar transistors PNP_1, PNP_3, and PNP_4, and the base-emitter junctions of the NPN bipolar junction transistors NPN_1 and NPN_2 of the electrostatic discharge protection circuit 110A and 110B are forward biased, so that the PNP bipolar junction transistors PNP_1, PNP_3, PNP_4 and the NPN bipolar junction transistors NPN_1, NPN_2 are triggered to ON at the same time. Since the PNP bipolar junction transistors PNP_3 and PNP_4 and the NPN-type bipolar junction transistors NPN_1 and NPN_2 of the electrostatic discharge protection circuit 110A and 110B are triggered to ON simultaneously, the semiconductor controlled rectifiers SCR-1 and SCR-2 are triggered to ON. The electrostatic discharge current may flow from the power pad PD_1, through the PNP bipolar junction transistor PNP_1 and the semiconductor controlled rectifiers SCR-1 and SCR-2 of the electrostatic discharge protection circuit 110A, 110B, and entering the power pad PD_2. The electrostatic discharge protection circuit 110A and 110B may prevent electrostatic discharge current from flowing through the core circuit 120 under protection.

As shown in FIGS. 3, 5, 7 and 9, the isolation feature S_4 between the doped regions P1 and N1 in the same well region W4 (and the well region W10) has a width DS1. Furthermore, the isolation feature S_6 between the doped regions P5 and N2 in the same well region W5 (and the well region W11) has a width DS2. In some embodiments, the sizes of the isolation features S_4 and S_6 are related to the effectiveness of the electrostatic discharge protection structures 400A, 400B. For example, in the direction 500 (FIG. s 7 and 9), the width DS1 of the isolation feature S_4 and the width DS2 of the isolation feature S_6 are proportional to the resistance values of the parasitic resistors R_1 and R_2. Therefore, with an appropriate layout area, the ratio of the electrostatic discharge current flow through the parasitic semiconductor controlled rectifiers SCR-1, SCR-2 and the parasitic PNP bipolar junction transistor PNP_1 may be adjusted by modifying the width DS1 and the width DS2. The holding voltage (V_{Hold}) of the electrostatic discharge protection devices 400A and 400B may be further adjusted to be greater than the operating voltage of the operating system 100. Therefore, the electrostatic discharge protection devices 400A and 400B are less susceptible to false triggering by noise voltage spikes and have a better human-body model (HBM) performance and a better machine model (MM) performance. For example, when an electrostatic discharge event occurs at the power pad PD_1 and the power pads PD_2 and PD_3 are coupled to ground, and the width DS1 and the width DS2 are 0 (i.e., the electrostatic discharge protection devices 400A and 400B are formed without the isolation features S_4 and S_6), the electrostatic discharge protection devices 400A and 400B may show the characteristic of a PNP bipolar junction transistor. When an electrostatic discharge event occurs at the power pad PD_1 and the power pads PD_2 and PD_3 are coupled to ground, and the width DS1 and the width DS2 is gradually increased, the parasitic semiconductor controlled rectifiers SCR-1 and SCR-2 will be triggered to ON earlier. Accordingly, the electrostatic discharge current flowing through the parasitic semiconductor controlled rectifiers SCR-1 and SCR-2 is gradually increased while the electrostatic discharge current flowing through the parasitic PNP bipolar junction transistor PNP_1 is gradually decreased. Moreover, the holding voltage (V_{Hold}) of the electrostatic discharge protection devices 400A and 400B will be decreased as the width DS1 and the width DS2 are increased.

Compared with the electrostatic discharge protection device 400A, the electrostatic discharge protection device 400B has longer distances between the collectors of the parasitic NPN bipolar junction transistors NPN_1, NPN_2 and the power pad PD_1 of (i.e., the parasitic resistance R_2 of the electrostatic discharge protection device 400B has a larger resistance value). When an electrostatic discharge event occurs at the power pad PD_1 and the power pads PD_2 and PD_3 are coupled to ground, the parasitic semiconductor controlled rectifiers SCR-1 and SCR-2 of the electrostatic discharge protection device 400B will be triggered to ON earlier. In addition, the electrostatic discharge protection device 400B may have a larger holding voltage (V_{Hold}) under the same layout area.

Embodiments of the present disclosure provide an electrostatic discharge protection device. The electrostatic discharge protection device includes a P-type semiconductor substrate, a deep N-type well region, a first well region, a first P-type doped region, a second well region, a second P-type doped region, a third well region, a third P-type doped region, a fourth well region, a fourth P-type doped region, a first N-type doped region, a fifth well region, a fifth P-type doped region and a second N-type doped region. The deep N-type well region is disposed in the P-type semiconductor substrate. The first well region is disposed on the deep N-type well region. The first P-type doped region is disposed in the first well region. The second well region is disposed on the deep N-type well region. The second P-type doped region is disposed in the second well region. The third well region is disposed on the deep N-type well region. The third P-type doped region is disposed in the third well region. The fourth well region is disposed on the deep N-type well region. The fourth P-type doped region is disposed in the fourth well region. The first N-type doped region is disposed in the fourth well region. The fifth well region is disposed on the deep N-type well region. The fifth P-type doped region is disposed in the fifth well region. The second N-type doped region is disposed in the fifth well region. The conductivity types of the first, third and fourth well regions are P-type. The conductivity types of the second and fifth well regions are N-type. The second P-type doped region, the fifth P-type doped region and the second N-type doped region are electrically connected to the first power pad. The first P-type doped region, the third P-type doped region, the fourth P-type doped region and the first N-type doped region are electrically connected to the second power pad.

The second P-type doped region, the second well region, the deep N-type well region, the first doped region and the first well region form a first parasitic PNP bipolar junction transistor. The first P-type doped region, the first well region, the deep N-type well region, the fifth well region, the second N-type doped region and the P-type semiconductor substrate form a second parasitic PNP bipolar junction transistor. The second P-type doped region, the second well region, the deep N-type well region and the third well region form a third parasitic PNP bipolar junction transistor. The fifth P-type doped region, the fifth well region, the deep N-type well region and the fourth well region form a fourth parasitic PNP bipolar junction transistor. The first N-type doped region, the fourth well region, the third well region, the deep N-type well region, the fifth well region and the second N-type doped region form a first parasitic NPN bipolar junction transistor. The first N-type doped region, the fourth well region, the deep N-type well region, the fifth well region and the second N-type doped region form a second parasitic NPN bipolar junction transistor. The P-type semiconductor substrate, the deep N-type well region, the fifth well region and the second N-type doped region form a first parasitic diode.

The collector of the first parasitic PNP bipolar junction transistor is coupled to the second power pad. The emitter of the first parasitic PNP bipolar junction transistor is coupled to the first power pad.

The emitter of the second parasitic PNP bipolar junction transistor is coupled to the second power pad. The collector of the second parasitic PNP bipolar junction transistor is coupled to the third power pad. The base of the second parasitic PNP bipolar junction transistor is coupled to the cathode of the first parasitic diode.

The emitter of the third parasitic PNP bipolar junction transistor is coupled to the first power pad. The base of the third parasitic PNP bipolar junction transistor is coupled to the base of the first parasitic PNP bipolar junction transistor.

The emitter of the first parasitic NPN bipolar junction transistor is coupled to the second power pad. The base of the first parasitic NPN bipolar junction transistor is coupled to the collector of the third parasitic PNP bipolar junction transistor. The collector of the first parasitic NPN bipolar junction transistor is coupled to the base of the third parasitic PNP bipolar junction transistor to form a first parasitic semiconductor controlled rectifier.

The emitter of the fourth parasitic PNP bipolar junction transistor is coupled to the first power pad. The base of the fourth parasitic PNP bipolar junction transistor is coupled to the collector of the second parasitic NPN bipolar junction transistor. The collector of the fourth parasitic PNP bipolar junction transistor is coupled to the base of the second parasitic NPN bipolar junction transistor to form a second parasitic semiconductor controlled rectifier.

The base of the second parasitic NPN bipolar junction transistor is coupled to the base of the first parasitic NPN bipolar junction transistor. The emitter of the second parasitic NPN bipolar junction transistor is coupled to the second power pad.

In addition, embodiments of the present disclosure provide an electrostatic discharge protection circuit for protecting a core circuit. The electrostatic discharge protection circuit includes a first PNP bipolar junction transistor, a second PNP bipolar junction transistor, a first diode, a third PNP bipolar junction transistor, a first NPN bipolar junction transistor, a fourth PNP bipolar junction transistor, a second NPN bipolar junction transistor, a first resistor, a second resistor, a third resistor and a fourth resistor. The emitter of the first PNP bipolar junction transistor is coupled to a first power pad. The collector of the first PNP bipolar junction transistor is coupled to a second power pad. The emitter of the second PNP bipolar junction transistor is coupled to the second power pad. The collector of the second PNP bipolar junction transistor is coupled to a third power pad. The cathode of the first diode is coupled to the first power pad and the base of the second PNP bipolar junction transistor. The anode of the first diode is coupled to the third power pad. The emitter of the third PNP bipolar junction transistor is coupled to the first power pad. The base of the third PNP bipolar junction transistor is coupled to the base of the first PNP bipolar junction transistor. The emitter of the first NPN bipolar junction transistor is coupled to the second power pad. The base of the first NPN bipolar junction transistor is coupled to the collector of the third PNP bipolar junction transistor, and the collector of the first NPN bipolar junction transistor is coupled to the base of the third PNP bipolar junction transistor to form a first semiconductor controlled rectifier. The emitter of the fourth PNP bipolar junction transistor is coupled to the first power pad. The emitter of the second NPN bipolar junction transistor is coupled to the second power pad. The base of the fourth PNP bipolar junction transistor is coupled to the collector of the second NPN bipolar junction transistor, and the collector of the fourth PNP bipolar junction transistor is coupled to the base of the second NPN bipolar junction transistor to form a second semiconductor controlled rectifier. The base of the first NPN bipolar junction transistor is coupled to the base of the second NPN bipolar junction transistor. The first resistor is coupled between the first power pad and the base of the first PNP bipolar junction transistor. The second resistor is coupled between the first power pad and the base of the fourth PNP bipolar junction transistor. The third resistor is coupled between the second power pad and the base of the first NPN bipolar junction transistor. The fourth resistor is coupled between the second power pad and the base of the second NPN bipolar junction transistor.

The equivalent circuit of the electrostatic discharge protection device and the electrostatic discharge protection circuit according to the embodiments of the present disclosure show the characteristics of both a PNP bipolar junction transistor and a semiconductor controlled rectifier. When an electrostatic discharge event occurs at the first power pad and the second power pad is grounded, the first (parasitic) PNP bipolar junction transistor, the first (parasitic) semiconductor controlled rectifier, and the second (parasitic) semiconductor controlled rectifier are triggered to ON. Accordingly, the electrostatic discharge current may flow from the first power pad, through the first (parasitic) PNP bipolar junction transistor, the first (parasitic) semiconductor controlled rectifier and the second (parasitic) semiconductor controlled rectifier of the equivalent circuit of the electrostatic discharge protection device or the electrostatic discharge protection circuit and entering the second power pad. The equivalent circuit of the electrostatic discharge protection device and the electrostatic discharge protection circuit may prevent electrostatic discharge current from flowing through the core circuit under protection.

In some embodiments, the width (for example, the width DS1) of the isolation feature between the P-type doped region and the first N-type doped region in the fourth well region and the width (for example, the width DS2) of the isolation feature between the fifth P-type doped region and the second N-type doped region in the fifth well region can be adjusted to modify the ratio of the electrostatic discharge current flowing through the first (parasitic) PNP bipolar junction transistor, the first (parasitic) semiconductor controlled rectifier and the second (parasitic) semiconductor controlled rectifier. The holding voltage (V_{Hold}) of the electrostatic discharge protection device (or the electrostatic discharge protection circuit) may be further adjusted to be greater than the operating voltage of the operating system. Therefore, the electrostatic discharge protection device is less susceptible to false triggering by noise voltage spikes and have a better human-body model (HBM) performance and a better machine model (MM) performance.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge protection device, comprising:
a P-type semiconductor substrate;
a deep N-type well region disposed in the P-type semiconductor substrate;
a first well region disposed on the deep N-type well region;
a first P-type doped region disposed in the first well region;
a second well region disposed on the deep N-type well region;
a second P-type doped region disposed in the second well region;
a third well region disposed on the deep N-type well region;
a third P-type doped region disposed in the third well region;
a fourth well region disposed on the deep N-type well region;
a fourth P-type doped region disposed in the fourth well region;
a first N-type doped region disposed in the fourth well region;
a fifth well region disposed on the deep N-type well region;
a fifth P-type doped region disposed in the fifth well region; and
a second N-type doped region disposed in the fifth well region,
wherein the conductivity types of the first well region, the third well region and the fourth well region are P-type, and the conductivity types of the second well region and the fifth well region are N-type,
wherein the second P-type doped region, the fifth P-type doped region and the second N-type doped region are electrically connected to a first power pad, and
wherein the first P-type doped region, the third P-type doped region, the fourth P-type doped region and the first N-type doped region are electrically connected to a second power pad.

2. The electrostatic discharge protection device as claimed in claim 1, wherein the fourth P-type doped region is adjacent to the first P-type doped region and the third P-type doped region, and is separated from the second P-type doped region.

3. The electrostatic discharge protection device as claimed in claim 2, wherein the fourth P-type doped region is located between the third P-type doped region and the first N-type doped region.

4. The electrostatic discharge protection device as claimed in claim 2, wherein the first N-type doped region is located between the fourth P-type doped region and the fifth P-type doped region.

5. The electrostatic discharge protection device as claimed in claim 1, wherein the first N-type doped region is adjacent to the first P-type doped region and the third P-type doped region, and is separated from the second P-type doped region.

6. The electrostatic discharge protection device as claimed in claim 5, wherein the first N-type doped region is located between the third P-type doped region and the fourth P-type doped region.

7. The electrostatic discharge protection device as claimed in claim 5, wherein the fourth P-type doped region is located between the first N-type doped region and the fifth P-type doped region.

8. The electrostatic discharge protection device as claimed in claim 1, further comprising:
a first isolation feature disposed in the fourth well region and isolating the fourth P-type doped region from the first N-type doped region; and
a second isolation feature disposed in the fifth well region and isolating the fifth P-type doped region from the second N-type doped region.

9. The electrostatic discharge protection device as claimed in claim 1, further comprising:
a first silicide feature covering the third P-type doped region;
a second silicide feature covering the fourth P-type doped region; and
a third silicide feature covering the first N-type doped region, wherein the first silicide feature, the second silicide feature and the third silicide feature are spaced apart from each other.

10. The electrostatic discharge protection device as claimed in claim 9, further comprising:
a fourth silicide feature covering the first P-type doped region;
a fifth silicide feature covering the second P-type doped region;
a sixth silicide feature covering the fifth P-type doped region; and
a seventh silicide feature covering the second N-type doped region, wherein the fourth silicide feature, the fifth silicide feature, the sixth silicide feature and the seventh silicide feature are spaced apart from each other;
a first interconnect structure directly connected to the first silicide feature, the second silicide feature, the third silicide feature and the fourth silicide feature; and
a second interconnect structure directly connected to the fifth silicide feature, the sixth silicide feature and the seventh silicide feature.

11. The electrostatic discharge protection device as claimed in claim 1, wherein:
the second N-type doped region, the second well region, the deep N-type well region, the first P-type doped region and the first well region form a first parasitic PNP bipolar junction transistor,
the first P-type doped region, the first well region, the deep N-type well region, the fifth well region, the second N-type doped region and the P-type semiconductor substrate form a second parasitic PNP bipolar junction transistor,
the second N-type doped region, the second well region, the deep N-type well region and the third well region form a third parasitic PNP bipolar junction transistor,
the fifth P-type doped region, the fifth well region, the deep N-type well region and the fourth well region form a fourth parasitic PNP bipolar junction transistor,
the first N-type doped region, the fourth well region, the third well region, the deep N-type well region, the fifth well region and the second N-type doped region form a first parasitic NPN bipolar junction transistor,
the first N-type doped region, the fourth well region, the deep N-type well region, the fifth well region and the second N-type doped region form a second parasitic NPN bipolar junction transistor,
the P-type semiconductor substrate, the deep N-type well region, the fifth well region and the second N-type doped region form a first parasitic diode,
a collector of the first parasitic PNP bipolar junction transistor is coupled to the second power pad,
an emitter of the first parasitic PNP bipolar junction transistor is coupled to the first power pad,
an emitter of the second parasitic PNP bipolar junction transistor is coupled to the second power pad,
a collector of the second parasitic PNP bipolar junction transistor is coupled to a third power pad,
a base of the second parasitic PNP bipolar junction transistor is coupled to a cathode of the first parasitic diode,
an emitter of the third parasitic PNP bipolar junction transistor is coupled to the first power pad,
a base of the third parasitic PNP bipolar junction transistor is coupled to a base of the first parasitic PNP bipolar junction transistor, an emitter of the first parasitic NPN bipolar junction transistor is coupled to the second power pad,
a base of the first parasitic NPN bipolar junction transistor is coupled to a collector of the third parasitic PNP bipolar junction transistor, and a collector of the first parasitic NPN bipolar junction transistor is coupled to the base of the third parasitic PNP bipolar junction transistor to form a first parasitic semiconductor controlled rectifier,
an emitter of the fourth parasitic PNP bipolar junction transistor is coupled to the first power pad,
a base of the fourth parasitic PNP bipolar junction transistor is coupled to a collector of the second parasitic NPN bipolar junction transistor, and a collector of the fourth parasitic PNP bipolar junction transistor is coupled to a base of the second parasitic NPN bipolar junction transistor to form a second parasitic semiconductor controlled rectifier,
the base of the second parasitic NPN bipolar junction transistor is coupled to the base of the first parasitic NPN bipolar junction transistor, and
an emitter of the second parasitic NPN bipolar junction transistor is coupled to the second power pad.

12. The electrostatic discharge protection device as claimed in claim 11, wherein:
the base of the first parasitic PNP bipolar junction transistor, the collector of the first parasitic NPN bipolar junction transistor and the base of the third parasitic PNP bipolar junction transistor are coupled to the first power pad through a first parasitic resistance formed by the deep N-type well region.

13. The electrostatic discharge protection device as claimed in claim 11, wherein:
the base of the fourth parasitic PNP bipolar junction transistor and the collector of the second parasitic NPN bipolar junction transistor are coupled to the first power pad through a second parasitic resistance formed by the deep N-type well region.

14. The electrostatic discharge protection device as claimed in claim 11, further comprising:
a sixth well region disposed in the P-type semiconductor substrate;
a sixth P-type doped region disposed in the sixth well region;
a seventh well region disposed between the first well region and the first P-type doped region;
an eighth well region disposed between the second well region and the second P-type doped region;
a ninth well region disposed between the third well region and the third P-type doped region;
a tenth well region disposed between the fourth well region and the fourth P-type doped region and between the fourth well region and the first N-type doped region;
an eleventh well region disposed between the fifth well region and the fifth P-type doped region and between the fifth well region and the second N-type doped region;
a twelfth well region disposed between the sixth well region and the sixth P-type doped region,
wherein the conductivity types of the sixth well region, the seventh well region, the ninth well region, the tenth well region and the twelfth well region are P-type, and
the conductivity types of the eighth well region and the eleventh well region are N-type.

15. The electrostatic discharge protection device as claimed in claim 14, wherein:
the collector of the third parasitic PNP bipolar junction transistor and the base of the first parasitic NPN bipolar junction transistor are coupled to the second power pad through a third parasitic resistor formed by the tenth well region, and
the collector of the fourth parasitic PNP bipolar junction transistor and the base of the second parasitic NPN bipolar junction transistor are coupled to the second power pad through a fourth parasitic resistor formed by the tenth well region.

16. The electrostatic discharge protection device as claimed in claim 14, wherein:
the collector of the third parasitic PNP bipolar junction transistor and the base of the first parasitic NPN bipolar junction transistor are coupled to the second power pad through a fifth parasitic resistor formed by the ninth well region, and
the collector of the fourth parasitic PNP bipolar junction transistor and the base of the second parasitic NPN bipolar junction transistor are coupled to the second power pad through a sixth parasitic resistance formed by the ninth well region.

17. The electrostatic discharge protection device as claimed in claim 11, wherein when an electrostatic discharge event occurs at the first power pad and the second power pad is grounded, the first parasitic PNP bipolar transistor, the first parasitic semiconductor controlled rectifier and the second parasitic semiconductor controlled rectifier are triggered to ON.

18. An electrostatic discharge protection circuit for protecting a core circuit, comprising:
a first PNP bipolar junction transistor, wherein an emitter of the first PNP bipolar junction transistor is coupled to a first power pad, and a collector of the first PNP bipolar junction transistor is coupled to a second power pad;
a second PNP bipolar junction transistor, wherein an emitter of the second PNP bipolar junction transistor is coupled to the second power pad, and a collector of the second PNP bipolar junction transistor is coupled to a third power pad;
a first diode has a cathode and an anode, wherein the cathode of the first diode is coupled to the first power pad and a base of the second PNP bipolar junction transistor, and the anode of the first diode is coupled to the third power pad;
a third PNP bipolar junction transistor, wherein an emitter of the third PNP bipolar junction transistor is coupled to the first power pad, and a base of the third PNP bipolar junction transistor is coupled to a base electrode of the first PNP bipolar junction transistor;
a first NPN bipolar junction transistor, wherein an emitter of the first NPN bipolar junction transistor is coupled to the second power pad, a base of the first NPN bipolar junction transistor is coupled to a collector of the third PNP bipolar junction transistor, and a collector of the first NPN bipolar junction transistor is coupled to the base of the third PNP bipolar junction transistor to form a first semiconductor controlled rectifier;
a fourth PNP bipolar junction transistor, wherein an emitter of the fourth PNP bipolar junction transistor is coupled to the first power pad;
a second NPN bipolar junction transistor, wherein an emitter of the second NPN bipolar junction transistor is coupled to the second power pad, a base of the fourth PNP bipolar junction transistor is coupled to a collector of the second NPN bipolar junction transistor, and a collector of the fourth PNP bipolar junction transistor is coupled to a base of the second NPN the bipolar junction transistor to form a second semiconductor controlled rectifier, and
wherein the base of the first NPN bipolar junction transistor is coupled to the base of the second NPN bipolar junction transistor;
a first resistor coupled between the first power pad and the base of the first PNP bipolar junction transistor;
a second resistor coupled between the first power pad and the base of the fourth PNP bipolar junction transistor;
a third resistor coupled between the second power pad and the base of the first NPN bipolar junction transistor; and
a fourth resistor is coupled between the second power pad and the base of the second NPN bipolar junction transistor.

19. The electrostatic discharge protection circuit as claimed in claim 18, wherein the first PNP bipolar junction transistor, the second PNP bipolar junction transistor, the third PNP bipolar junction transistor, the fourth PNP bipolar junction transistor, the first NPN bipolar junction transistor, the second NPN bipolar junction transistor, the first resistor, the second resistor and the third resistor share the same substrate.

20. The electrostatic discharge protection circuit of claim 18, wherein when an electrostatic discharge event occurs at the first power pad and the second power pad is grounded, the first PNP bipolar junction transistor, the first semiconductor controlled rectifier and the second semiconductor controlled rectifier are triggered to ON.
